(19) United States
(12) Patent Application Publication
(10) Pub. No.: US 2011/0049704 A1
(43) Pub. Date: Mar. 3, 2011

(54) SEMICONDUCTOR DEVICE PACKAGES WITH INTEGRATED HEATSINKS

(75) Inventors: Yu-Ching Sun, Jhongli City (TW); Fa-Hao Wu, Jhongli City (TW); Kuang-Hsiung Chen, Jhongli City (TW)

(73) Assignee: Advanced Semiconductor Engineering, Inc.

(21) Appl. No.: 12/770,627

(22) Filed: Apr. 29, 2010

(30) Foreign Application Priority Data
Aug. 31, 2009 (TW) 98129294

(51) Int. Cl. H01L 23/488; H01L 23/12; H01L 23/28; H01L 23/34; H01L 21/56; H01L 21/60

(52) U.S. Cl. 257/737; 438/122; 257/E23.003; 257/E23.07; 257/E23.116; 257/E23.08; 257/E21.502; 257/E21.506

(57) ABSTRACT

In one embodiment, a semiconductor device package includes a circuit substrate, a chip, a plurality of first solder balls, an encapsulant, and a heatsink. The circuit substrate includes a carrying surface and a plurality of first bonding pads thereon. The chip is disposed on the carrying surface and electrically connected to the circuit substrate. The first bonding pads are located outside of the chip. The first solder balls are disposed on the first bonding pads. The encapsulant is disposed on the carrying surface and covers the chip. The encapsulant includes a plurality of openings exposing the first solder balls. The heatsink is disposed over the encapsulant and bonded to the first solder balls, wherein the heatsink includes a plurality of protrusions on a bonding surface facing the encapsulant, and the protrusions are correspondingly embedded into the first solder balls.

### CROSS REFERENCE TO RELATED APPLICATION

This application claims the benefit of Taiwan Application Serial No. 98129294, filed on Aug. 31, 2009, the disclosure of which is incorporated herein by reference in its entirety.

### FIELD OF THE INVENTION

The invention relates to semiconductor device packages and related processes. More particularly, the invention relates to semiconductor device packages and related processes that are integrated with a heatsink.

### BACKGROUND

In the semiconductor industry, the production of integrated circuits (ICs) mainly includes three stages: wafer manufacturing, IC manufacturing, and IC packaging. Chips (e.g., dies) are fabricated by forming ICs on a wafer and then sawing the wafer. Each individual chip that is obtained by sawing the wafer can be electrically connected to external signals via contacts on the chip, and an encapsulant is applied to cover the chip for packaging the chip. The objective of the resulting package is to protect the chip from the external environment, such as moisture, interference, and so forth, and, at the same time, provide a medium for electrical connection between the chip and an external circuit.

With the increasing demand for integrity of ICs, semiconductor device packages are becoming more complicated and varied. In particular, a package is desirably provided with a heatsink thereon to improve heat dissipation ability thereof. In previous approaches, the heatsink is typically attached onto a surface of the package via an adhesive. However, this bonding manner can be incapable of fixing the heatsink steadily on the package, such that the heatsink can be prone to peeling or becoming separated from the package, thereby degrading the production yield and the utilization reliability.

It is against this background that a need arose to develop the semiconductor device packages and related processes described herein.

### SUMMARY

Embodiments of the invention provide a semiconductor device package including a heatsink tightly integrated with a main body of the package to achieve high reliability. Embodiments of the invention further provide a process for manufacturing the above package integrated with the heatsink to improve heat dissipation effect of the package, wherein the heatsink is tightly fixed on the main body of the package.

As embodied and broadly described herein, a package includes a circuit substrate, a chip, a plurality of first solder balls, an encapsulant, and a heatsink. The circuit substrate includes a carrying surface and a plurality of first bonding pads thereon. The chip is disposed on the carrying surface and electrically connected to the circuit substrate. The first bonding pads are located outside of the chip. The first solder balls are disposed on the first bonding pads. The encapsulant is disposed on the carrying surface and covers the chip. The encapsulant defines a plurality of openings exposing the first solder balls. The heatsink is disposed over the encapsulant and bonded to the first solder balls, wherein the heatsink includes a plurality of protrusions on a bonding surface facing the encapsulant, and the protrusions are correspondingly embedded into the first solder balls.

Embodiments of the invention are further directed to a manufacturing process. First, a circuit substrate is provided. The circuit substrate includes a carrying surface and a plurality of first bonding pads thereon. Then, a first solder ball is formed on each first bonding pad, and a chip is disposed on the carrying surface, wherein the first solder balls are located outside of the chip. Next, an encapsulant is disposed on the carrying surface to cover the chip. Thereafter, a plurality of openings are formed in the encapsulant, wherein the openings respectively expose the first solder balls. Then, a heatsink is disposed over the encapsulant and bonded to the first solder balls. The heatsink includes a plurality of protrusions on a bonding surface facing the encapsulant, and the protrusions are correspondingly embedded into the first solder balls.

In an embodiment, a heatsink contacts an encapsulant. In an embodiment, first bonding pads are grounding pads. In an embodiment, a sidewall of each opening and a corresponding first solder ball in the opening are spaced from each other with a gap therebetween. In an embodiment, an edge of an encapsulant is aligned with an edge of a circuit substrate. In an embodiment, a package further includes a plurality of wires connected between a chip and a circuit substrate. In an embodiment, a circuit substrate further includes a bottom surface opposite to a carrying surface and a plurality of second bonding pads on the bottom surface. In addition, each second bonding pad may be provided with a second solder ball disposed thereon. In an embodiment, openings are formed in an encapsulant via laser ablation.

Accordingly, embodiments of the invention embed first solder balls in an encapsulant and dispose a heatsink on the encapsulant to bond with the first solder balls. Since protrusions on a bottom of the heatsink are correspondingly embedded into the first solder balls, the heatsink can be tightly fixed on the encapsulant and a circuit substrate. Therefore, the heat dissipation effect of the resulting package can be improved, and the reliability of the package is enhanced.

Other aspects and embodiments of the invention are also contemplated. The foregoing summary and the following detailed description are not meant to restrict the invention to any particular embodiment but are merely meant to describe some embodiments of the invention.

### BRIEF DESCRIPTION OF THE DRAWINGS

For a better understanding of the nature and objects of some embodiments of the invention, reference should be made to the following detailed description taken in conjunction with the accompanying drawings. In the drawings, like reference numbers denote like elements, unless the context clearly dictates otherwise.

FIG. 1A through FIG. 1C schematically show a semiconductor device package according to an embodiment of the invention.

FIG. 2 shows a manufacturing process of the package of FIG. 1A through FIG. 1C, according to an embodiment of the invention.

### DETAILED DESCRIPTION

### Definitions

The following definitions apply to some of the aspects described with respect to some embodiments of the invention. These definitions may likewise be expanded upon herein.

As used herein, the singular terms “a,” and “the” include plural referents unless the context clearly dictates otherwise. Thus, for example, reference to a chip can include multiple chips unless the context clearly dictates otherwise.

As used herein, the term “set” refers to a collection of one or more components. Thus, for example, a set of solder balls can include a single solder ball or multiple solder balls. Components of a set also can be referred to as members of the set. Components of a set can be the same or different. In some instances, components of a set can share one or more common characteristics.

As used herein, the term “adjacent” refers to being near or adjoining. Adjacent components can be spaced apart from one another or can be in actual or direct contact with one another. In some instances, adjacent components can be connected to one another or can be formed integrally with one another.

As used herein, relative terms, such as “inner,” “interior,” “outer,” “exterior,” “top,” “bottom,” “front,” “back,” “upper,” “upwardly,” “lower,” “downwardly,” “vertical,” “vertically,” “lateral,” “side,” “laterally,” “above,” and “below,” refer to an orientation of a set of components with respect to one another, such as in accordance with the drawings, but do not require a particular orientation of those components during manufacturing or use.

As used herein, the terms “connect,” “connected,” and “connection” refer to an operational coupling or linking. Connected components can be directly coupled to one another or can be indirectly coupled to one another, such as through another set of components.

As used herein, the terms “substantially” and “substantial” refer to a considerable degree or extent. When used in conjunction with an event or circumstance, the terms can refer to instances in which the event or circumstance occurs precisely as well as instances in which the event or circumstance occurs to a close approximation, such as accounting for typical tolerance levels of the manufacturing operations described herein.

As used herein, the terms “thermally conductive” and “thermal conductivity” refer to an ability to conduct heat. Thermally conductive materials typically correspond to those materials that exhibit little or no opposition to flow of heat. One measure of thermal conductivity is in terms of Watts per Kelvin per meter (W·K⁻¹·m⁻¹). Typically, a thermally conductive material is one having a conductivity greater than about 1 W·K⁻¹·m⁻¹, such as at least about 10 W·K⁻¹·m⁻¹ or at least about 10² W·K⁻¹·m⁻¹.Thermal conductivity of a material can sometimes vary with temperature. Unless otherwise specified, thermal conductivity of a material is defined at room temperature.

As used herein, the terms “electrically conductive” and “electrical conductivity” refer to an ability to transport an electric current. Electrically conductive materials typically correspond to those materials that exhibit little or no opposition to flow of an electric current. One measure of electrical conductivity is in terms of Siemens per meter (S·m⁻¹). Typically, an electrically conductive material is one having a conductivity greater than about 10⁴ S·m⁻¹, such as at least about 10⁵ S·m⁻¹ or at least about 10⁶ S·m⁻¹. Electrical conductivity of a material can sometimes vary with temperature. Unless otherwise specified, electrical conductivity of a material is defined at room temperature.

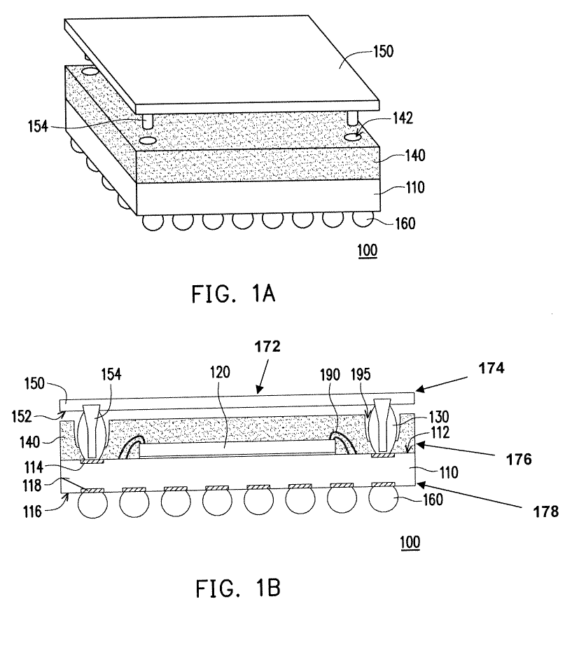

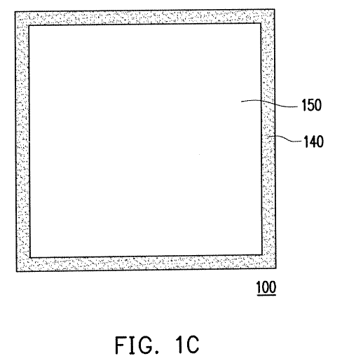

FIG. 1A through FIG. 1C schematically show a semiconductor device package according to an embodiment of the invention, wherein FIG. 1A is a perspective view, FIG. 1B is a sectional view, and FIG. 1C is a top view.

As shown in FIG. 1A through FIG. 1C, the package 100 includes a circuit substrate 110 including a carrying surface 112 and a set of first bonding pads 114 thereon. A chip 120 (or any other active or passive semiconductor device) is disposed on the carrying surface 112 of the circuit substrate 110 and electrically connected to the circuit substrate 110. The first bonding pads 114 are located outside edges or a periphery of the chip 120. In this embodiment, the chip 120 is electrically connected to the circuit substrate 110 via a set of wires 190 by wire bonding technique, and further electrically connected to the first bonding pads 114 via an internal circuit (not shown) of the circuit substrate 110. However, in other embodiments, the chip 120 can be electrically connected to the circuit substrate 110 by flip-chip bonding technique or in another manner. While the single chip 120 is shown, it is contemplated that multiple chips can be included, such as in a side-by-side manner or a stacked manner.

In addition, a set of first solder balls 130 (or another set of electrically conductive bumps) are respectively disposed on the first bonding pads 114, and an encapsulant 140 is disposed on the carrying surface 112 to partially or fully cover the chip 120. The encapsulant 140 includes, or is formed with, a set of openings 142 to expose the first solder balls 130. Furthermore, a heatsink 150 (or another heat dissipation structure) is disposed over the encapsulant 140 and bonded to the first solder balls 130. The heatsink 150 includes a plate-like portion, which includes a heat dissipation surface 172, which is a top surface facing away from the encapsulant 140, and a bonding surface 152, which is a bottom surface facing the encapsulant 140. In this embodiment, each of the bonding surface 152 and the heat dissipation surface 172 is substantially planar, although the shapes of the bonding surface 152 and the heat dissipation surface 172 can be varied for other embodiments, such as by including non-planar regions to enhance heat dissipation area. The heatsink 150 also includes a set of protrusions 154 on the bonding surface 152, and the protrusions 154 extend downwardly from the bonding surface 152 and are correspondingly embedded into the first solder balls 130. It is also contemplated that the first solder balls 130 can be implemented using an adhesive, such as an electrically conductive adhesive.

In this embodiment, the circuit substrate 110 further includes a bottom surface 116 opposite to the carrying surface 112 and a set of second bonding pads 118 on the bottom surface 116. Each second bonding pad 118 is provided with a second solder ball 160 (or another type of electrically conductive bump) thereon to electrically connect the package 100 to an external circuit, such as a printed circuit board.

This embodiment disposes the first solder balls 130 on the carrying surface 112 of the circuit substrate 110 and, after disposing the encapsulant 140 on the carrying surface 112, the openings 142 are formed in the encapsulant 140 to expose the first solder balls 130, so as to allow bonding of the circuit substrate 110 with the heatsink 150 via the first solder balls 130. The heatsink 150 can be tightly disposed over the circuit substrate 110 and the encapsulant 140 by the above manner. Furthermore, the heatsink 150 includes the protrusions 154 on the bonding surface 152 facing the encapsulant 140, and, thus, the protrusions 154 can be correspondingly embedded into the first solder balls 130 when bonding the heatsink 150 to the first solder balls 130 so as to improve bonding therebetween. If desired, an adhesive can be disposed between the heatsink 150 and the encapsulant 140 so as to further improve bonding therebetween.

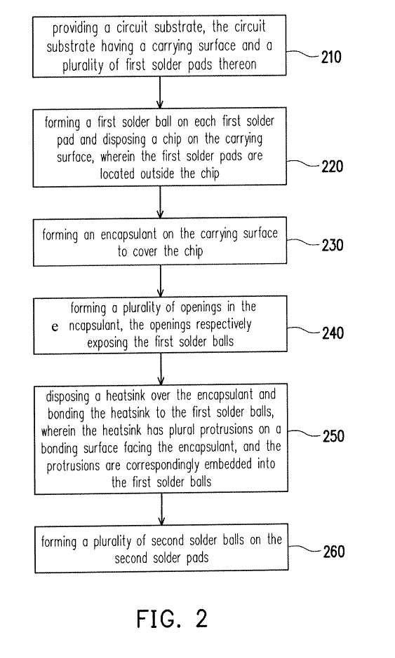

The following is a description of a manufacturing process and certain contemplated modifications of the package 100 of the above embodiment. FIG. 2 shows a manufacturing process of the package 100 of the above embodiment. At times, reference will be made to FIG. 1A through FIG. 1C, in conjunction with FIG. 2.

First, as shown in operation 210, a circuit substrate 110 is provided. In certain practical implementations, the embodiment may conduct various operations of the manufacturing process under the form of a substrate strip (or a substrate array) including a plurality of circuit substrates 110, and then the substrate strip is singulated or trimmed to form a plurality of package units separated from each other. Otherwise, the substrate strip can be trimmed into a plurality of circuit substrates 110, and then the aforementioned manufacturing process is performed on each of the separated circuit substrates 110.

It should be noted that performing the manufacturing process under the form of a substrate strip can conduct certain operations to multiple circuit substrates 110 of the substrate strip substantially simultaneously, so as to reduce the number of processing operations and the processing time.

Then, as shown in operation 220, a first solder ball 130 is disposed or formed on each first bonding pad 114, and a chip 120 is bonded to a carrying surface 112 of the circuit substrate 110, wherein the first solder balls 130 are located outside of the chip 120. In the foregoing operation, the first solder balls 130 can be disposed on the first bonding pads 114 first, and then the chip 120 can be bonded to the carrying surface 112 of the circuit substrate 110. Otherwise, the chip 120 can be bonded to the carrying surface 112 of the circuit substrate 110 first, and then the first solder balls 130 can be disposed on the first bonding pads 114. In other words, the present disclosure does not limit the order of forming the first solder balls 130 and bonding the chip 120. Moreover, as mentioned above, the chip 120 can be electrically connected to the circuit substrate 110 by flip-chip bonding technique or in another manner in operation 220.

Next, as shown in operation 230, an encapsulant 140 is disposed or formed on the carrying surface 112 of the circuit substrate 110 to cover the chip 120. In the case of performing the above process in the form of a substrate strip, the encapsulant 140 can be coated on substantially the entire substrate strip in operation 230, so as to cover the carrying surfaces 112 of multiple circuit substrates 110 of the substrate strip.

Thereafter, referring to operation 240, a set of openings 142 are formed in the encapsulant 140, wherein the openings 142 respectively expose the first solder balls 130. The method of forming the openings 142 can be laser ablation or another applicable manner, such as mechanical drilling, chemical etching, or plasma etching. For example, laser ablation can be carried out using a laser, which can be implemented in a number of ways, such as a green laser, an infrared laser, a solid-state laser, or a CO₂ laser. The laser can be implemented as a pulsed laser or a continuous wave laser. Suitable selection and control over operating parameters of the laser allow control over sizes and shapes of the openings 142. For certain implementations, a peak output wavelength of the laser can be selected in accordance with a particular composition of the encapsulant 140, and, for some implementations, the peak output wavelength can be in the visible range or the infrared range. Also, an operating power of the laser can be in the range of about 3 Watts to about 20 Watts, such as from about 3 Watts to about 15 Watts or from about 3 Watts to about 10 Watts. In the case of a pulsed laser implementation, a pulse frequency and a pulse duration are additional examples of operating parameters that can be suitably selected and controlled.

In addition, in order to ensure that the openings 142 can expose the first solder balls 130, the openings 142 can be configured in a size larger than that of the first solder balls 130, e.g., a sidewall of each opening 142 and a corresponding first solder ball 130 in the opening 142 are kept from each other or spaced apart with a gap 195 therebetween, and a lateral extent (e.g., a maximum lateral extent or an average of lateral extents along orthogonal directions) of the opening 142 adjacent to a top surface of the encapsulant 140 is greater than or equal to a lateral extent (e.g., a maximum lateral extent or an average of lateral extents along orthogonal directions) of the first solder ball 130. For example, a ratio of the lateral extent of the opening 142 (W_{O}) and the lateral extent of the first solder ball 130 (W_{SB}) can be represented as follows: W_{O}=aW_{SB}≧W_{SB}, where a is in the range of about 1 to about 1.5, such as from about 1.02 to about 1.3, from about 1.02 to about 1.2, or from about 1.05 to about 1.1.

In the case of performing the above process in the form of a substrate strip, the substrate strip can be trimmed prior to or after operation 240 to separate the circuit substrates 110 from each other and to separate the encapsulants 140 thereon. Since the circuit substrate 110 and the encapsulant 140 are trimmed substantially simultaneously, edges of the encapsulant 140 are substantially aligned with corresponding edges of the circuit substrate 110, e.g., such that lateral or sides surfaces 176 of the encapsulant 140 are substantially aligned or coplanar with corresponding lateral or sides surfaces 178 of the circuit substrate 110.

Then, referring to operation 250, a heatsink 150 is disposed over the encapsulant 140 and bonded to the first solder balls 130. The heatsink 150 includes a set of protrusions 154 corresponding to the first solder balls 130 and extending from a bonding surface 152 facing the encapsulant 140. The method of bonding the heatsink 150 to the first solder balls 130 can be performed as a reflow process of the first solder balls 130 to heat the first solder balls 130 into a melted state or a semi-melted state and correspondingly embedding the protrusions 154 of the heatsink 150 into the first solder balls 130. The first solder balls 130 can be tightly fixed to the protrusions 154 of the heatsink 150 after cooling.

The heatsink 150 can be in contact with or spaced apart from the encapsulant 140, which depends on the total height of each protrusion 154 of the heatsink 150 and the corresponding first solder ball 130 after being bonded together. In general, contacting the heatsink 150 with the encapsulant 140 can provide superior heat dissipation effect. The heatsink 150 can be formed from a variety of thermally conductive materials, such as a metal (e.g., aluminum or copper), a metal alloy, or a matrix with a metal or a metal alloy dispersed therein.

For certain embodiments, the heatsink 150 can further provide an electromagnetic interference (EMI) shielding effect in addition to the ability of heat dissipation. Specifically, the first bonding pads 114 can be configured as grounding pads to ground the heatsink 150 (serving as an EMI shield) when bonding the heatsink 150 with the first solder balls 130, so as to block undesirable, external signals from interfering with the chip 120 or to block signals produced by the chip 120 from interfering with an external circuit. In other embodiments, the heatsink 150 can be connected to a power plane or other signal drain or source to provide similar EMI shielding effect or meet other requirements of circuit design.

Moreover, the above manufacturing process can be performed in the form of a substrate strip, along with bonding the heatsink 150 (implemented as a strip or an array) to the first solder balls 130 and then trimming the substrate strip and the heatsink 150. By this manner, edges of the heatsink 150, corresponding edges of the encapsulant 140, and corresponding edges of the circuit substrate 110 are substantially aligned with one another, e.g., such that lateral or sides surfaces 174 of the heatsink 150 are substantially aligned or coplanar with corresponding lateral or sides surfaces 176 of the encapsulant 140 (and with corresponding lateral or sides surfaces 178 of the circuit substrate 110). In other embodiments, edges of the heatsink 150 can be inwardly recessed relative to corresponding edges of the encapsulant 140, as shown in FIG. 1C, or can extend beyond corresponding edges of the encapsulant 140 (not shown).

After that, as shown in operation 260, a set of second solder balls 160 are disposed or formed on a corresponding set of second bonding pads 118 on a bottom surface 116 of the circuit substrate 110, so as to connect the resulting package 100 to an external circuit, such as a printed circuit board.

In summary, semiconductor device packages and related processes described herein allow a heatsink to be tightly integrated and securely fixed over a circuit substrate and an encapsulant via solder balls on the circuit substrate. In addition, protrusions are formed on a bottom of the heatsink to be embedded into the solder balls, so as to enhance bonding between the heatsink and the solder balls. Therefore, the heat dissipation effect of the package can be improved, and the reliability of the package is enhanced. In addition, the heatsink can be connected to a ground plane, a power plane, or other signal drain or source, such as to provide EMI shielding effect or meet other requirements of circuit design. Furthermore, the process can be conducted under the form of a substrate strip, and then the substrate strip is trimmed to form a plurality of package units separated from each other. Thus, the manufacturing process can be simplified, and the processing time and the production cost can be reduced.

While the invention has been described with reference to the specific embodiments thereof, it should be understood by those skilled in the art that various changes may be made and equivalents may be substituted without departing from the true spirit and scope of the invention as defined by the appended claims. In addition, many modifications may be made to adapt a particular situation, material, composition of matter, method, or process to the objective, spirit and scope of the invention. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor device package, comprising:
a circuit substrate, including a carrying surface and a plurality of first bonding pads adjacent to the carrying surface;
a semiconductor device, disposed adjacent to the carrying surface and electrically connected to the circuit substrate, wherein the first bonding pads are located outside of a periphery of the semiconductor device;
a plurality of first, electrically conductive bumps, respectively disposed adjacent to the first bonding pads;
an encapsulant, disposed adjacent to the carrying surface and covering the semiconductor device, wherein the encapsulant defines a plurality of openings respectively exposing the first, electrically conductive bumps; and
a heatsink, disposed adjacent to the encapsulant and bonded to the first, electrically conductive bumps, wherein the heatsink includes a bonding surface facing the encapsulant and a plurality of protrusions extending from the bonding surface and towards the encapsulant, and the protrusions are respectively embedded into the first, electrically conductive bumps.

2. The semiconductor device package of claim 1, wherein the heatsink contacts the encapsulant.

3. The semiconductor device package of claim 1, wherein the first bonding pads are grounding pads, and the heatsink is configured as an electromagnetic interference shield.

4. The semiconductor device package of claim 1, wherein a sidewall of at least one of the openings and a respective one of the first, electrically conductive bumps are spaced apart with a gap therebetween.

5. The semiconductor device package of claim 1, wherein a lateral extent W_{O} of at least one of the openings adjacent to a top surface of the encapsulant and a lateral extent W_{SB} of a respective one of the first, electrically conductive bumps are represented as follows: W_{O}=aW_{SB}≧W_{SB}, wherein a is in the range of 1 to 1.5.

6. The semiconductor device package of claim 5, wherein a is in the range of 1.02 to 1.3.

7. The semiconductor device package of claim 1, wherein an edge of the heatsink is substantially aligned with an edge of the encapsulant.

8. The semiconductor device package of claim 7, wherein the edge of the encapsulant is substantially aligned with an edge of the circuit substrate.

9. The semiconductor device package of claim 1, further comprising a plurality of wires connected between the semiconductor device and the circuit substrate.

10. The semiconductor device package of claim 1, wherein the circuit substrate further includes a bottom surface opposite to the carrying surface and a plurality of second bonding pads adjacent to the bottom surface.

11. The semiconductor device package of claim 10, further comprising a plurality of second, electrically conductive bumps respectively disposed adjacent to the second bonding pads.

12. A manufacturing process, comprising:
providing a circuit substrate, wherein the circuit substrate includes a carrying surface and a plurality of first bonding pads adjacent to the carrying surface;
disposing a first, electrically conductive bump adjacent to each of the first bonding pads;
disposing a semiconductor device adjacent to the carrying surface, wherein the first bonding pads are located outside of a periphery of the semiconductor device;
disposing an encapsulant adjacent to the carrying surface to cover the semiconductor device;
forming a plurality of openings in the encapsulant, wherein the openings expose respective ones of the first, electrically conductive bumps; and
disposing a heat dissipation structure adjacent to the encapsulant, wherein the heat dissipation structure includes a plurality of protrusions facing the encapsulant, and the protrusions are embedded into respective ones of the first, electrically conductive bumps.

13. The manufacturing process of claim 12, wherein disposing the heat dissipation structure is such that the heat dissipation structure contacts the encapsulant.

14. The manufacturing process of claim 12, wherein the first bonding pads are grounding pads, and the heat dissipation structure is configured as an electromagnetic interference shield.

15. The manufacturing process of claim 12, wherein forming the openings is carried out by laser ablation.

16. The manufacturing process of claim 12, wherein forming the openings is such that a sidewall of at least one of the openings and a respective one of the first, electrically conductive bumps are spaced apart with a gap therebetween.

17. The manufacturing process of claim 12, wherein forming the openings is such that a lateral extent W_{O} of at least one of the openings adjacent to a top surface of the encapsulant and a lateral extent W_{SB} of a respective one of the first, electrically conductive bumps are represented as follows: W_{O}=aW_{SB}≧W_{SB}, wherein a is at least 1.

18. The manufacturing process of claim 17, wherein a is in the range of 1 to 1.5.

19. The manufacturing process of claim 12, wherein the circuit substrate further includes a bottom surface opposite to the carrying surface and a plurality of second bonding pads adjacent to the bottom surface, and the manufacturing process further comprises disposing a plurality of second, electrically conductive bumps adjacent to respective ones of the second bonding pads.

20. The manufacturing process of claim 12, wherein disposing the heat dissipation structure is such that side surfaces of the heat dissipation structure are substantially aligned with respective ones of side surfaces of the encapsulant.
